(19) United States
(12) Patent Application Publication
(10) Pub. No.: US 2026/0095143 A1
(43) Pub. Date: Apr. 2, 2026

(54) SAW DEVICE HAVING MULTIPLE FILTER BANDS AND METHOD FOR MANUFACTURING THE SAME

(71) Applicant: WISOL CO., LTD., Gyeonggi-do (KR)

(72) Inventors: Sang Ki Bae, Gyeonggi-do (KR); Sung Hyun Lee, Gyeonggi-do (KR)

(21) Appl. No.: 19/341,287

(22) Filed: Sep. 26, 2025

(30) Foreign Application Priority Data
Sep. 30, 2024 (KR) 10-2024-0132711

(51) Int. Cl. H03H 9/02; H03H 3/08; H03H 9/145; H03H 9/64

(52) U.S. Cl. CPC H03H 9/02897; H03H 3/08; H03H 9/145; H03H 9/64

(57) ABSTRACT

Provided is a method for manufacturing a surface acoustic wave (SAW) device having multiple filter bands according to the present invention comprises: forming a first electrode layer on an upper portion of a substrate; forming a second electrode layer at a position adjacent to a formation position of the first electrode layer on the upper portion of the substrate; forming a wiring defect prevention layer surrounding one end of the first electrode layer and the other end of the second electrode layer; and forming a metal wiring layer on upper portions of the first electrode layer, the second electrode layer, and the wiring defect prevention layer.

### CROSS-REFERENCE TO RELATED APPLICATION

This application claims priority from Korean Patent Application No. 10-2024-0132711 filed on Sep. 30, 2024 in the Korean Intellectual Property Office, the contents of which in its entirety are herein incorporated by reference.

### FIELD

The present invention relates to a surface acoustic wave (SAW) device, and more particularly, to a technique for manufacturing a SAW device having multiple filter bands.

### BACKGROUND

In general, a surface acoustic wave (SAW) device having multiple filter bands applies different electrode layer thicknesses or structures to each band to achieve the optimal performance in each filter band.

Since such a SAW device having multiple filter bands forms an electrode layer for each band, a metal gap exists between different filter bands, and a wiring layer is formed above the metal gap to connect the electrical characteristics of the respective filter bands.

FIG. 1 is a reference diagram illustrating problems occurring in a conventional SAW device.

FIG. 1(a) illustrates a state in which a void or crack occurs in a metal wiring layer directly formed on a first electrode layer and a second electrode layer constituting a SAW device, and FIG. 1(b) illustrates a cross-sectional image of an actual SAW device, obtained by focused ion beam (FIB). As shown therein, voids or cracks are generated in the metal wiring layer due to the metal wiring layer being formed directly on the first electrode layer and the second electrode layer, which causes deterioration in the durability of the SAW device.

### DETAILED DESCRIPTION OF THE INVENTION

### Technical Problem

An objective of the present invention is to provide a method for manufacturing a surface acoustic wave (SAW) device having multiple filter bands, which can prevent damage to a metal wiring layer formed in the SAW device.

### Technical Solution

A method for manufacturing a surface acoustic wave (SAW) device having multiple filter bands according to the present invention includes: forming a first electrode layer on an upper portion of a substrate; forming a second electrode layer at a position adjacent to a formation position of the first electrode layer on the upper portion of the substrate; forming a wiring defect prevention layer surrounding one end of the first electrode layer and the other end of the second electrode layer; and forming a metal wiring layer on upper portions of the first electrode layer, the second electrode layer, and the wiring defect prevention layer.

The forming of the wiring defect prevention layer may include forming the wiring defect prevention layer to surround the one end of the first electrode layer and the other end of the second electrode layer such that the following equation is satisfied:

W0<(W1−W2)/2 [Equation]

Here, W0 refers to an overlap width between the one end of the first electrode layer or the other end of the second electrode layer and the wiring defect prevention layer, W1 refers to the width of the metal wiring layer, and W2 refers to the spacing width between one end of the first electrode layer and the other end of the second electrode layer.

The forming of the wiring defect prevention layer may include forming a photoresist layer on the upper portions of the first electrode layer and the second electrode layer after the first electrode layer and the second electrode layer are formed, and forming the wiring defect prevention layer through an exposure process and a development process on the photoresist layer.

The wiring defect prevention layer may include a material in which a photosensitive agent, a binder, a solvent, and an additive are mixed, wherein the photosensitive agent includes a diazonaphthoquinone material, the binder includes a novolac resin, a PHS+acrylate resin, or a PHS+cycloolefin resin, and the solvent includes propylene glycol monomethyl ether acetate (PGMEA), propylene glycol monomethyl ether (PGME), γ-butyrolactone (GBL), ethylene glycol butyl ether (EGBE), glycol ethers, cyclohexanone, or anisole.

A SAW device having multiple filter bands of the present invention includes: a substrate; a first electrode layer formed on an upper portion of the substrate; a second electrode layer formed at a position adjacent to a formation position of the first electrode layer on the upper portion of the substrate; a wiring defect prevention layer formed on an upper portion of one end of the first electrode layer and an upper portion of the other end of the second electrode layer so as to surround the one end of the first electrode layer and the other end of the second electrode layer; and a metal wiring layer formed on upper portions of the first electrode layer, the second electrode layer, and the wiring defect prevention layer.

The wiring defect prevention layer may surround the one end of the first electrode layer and the other end of the second electrode layer so as to satisfy the following equation.

W0<(W1−W2)/2 [Equation]

Here, W0 refers to an overlap width between one end of the first electrode layer or the other end of the second electrode layer and the wiring defect prevention layer, W1 refers to the width of the metal wiring layer, and W2 refers to the spacing width between one end of the first electrode layer and the other end of the second electrode layer.

The wiring defect prevention layer may include a material in which a photosensitive agent, a binder, a solvent, and an additive are mixed, wherein the photosensitive agent includes a diazonaphthoquinone material, the binder includes a novolac resin, a PHS+acrylate resin, or a PHS+cycloolefin resin, and the solvent includes propylene glycol monomethyl ether acetate (PGMEA), propylene glycol monomethyl ether (PGME), γ-butyrolactone (GBL), ethylene glycol butyl ether (EGBE), glycol ethers, cyclohexanone, or anisole.

In the SAW device, the one end of the first electrode layer and the other end of the second electrode layer may have different heights.

### Effects of the Invention

According to the present invention, by forming a wiring defect prevention layer between a first electrode layer and a second electrode layer before forming a metal wiring layer in a surface acoustic wave (SAW) device, a buffer region between the first and second electrode layers and the metal wiring layer is secured, thereby preventing cracks or voids from occurring in the metal wiring layer.

In addition, deterioration in product reliability and performance caused by cracks or voids occurring in the metal wiring layer can be preemptively prevented.

### BRIEF DESCRIPTION OF THE DRAWINGS

FIG. 1 is a reference diagram illustrating problems occurring in a conventional surface acoustic wave (SAW) device.

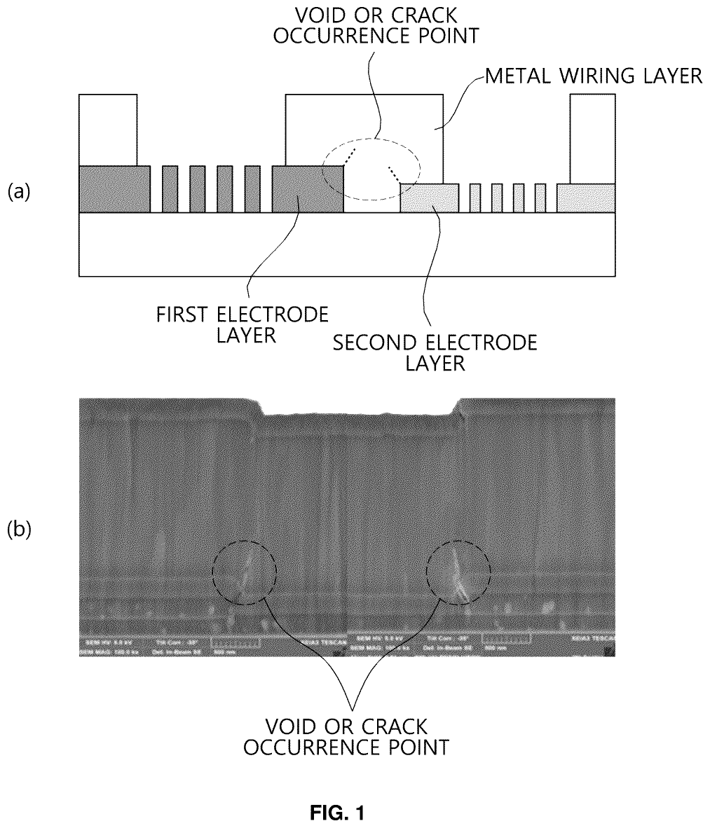

FIG. 2 is a side view illustrating a SAW device having multiple filter bands according to the present invention.

FIG. 3 is a reference diagram illustrating the structure of a wiring defect prevention layer constituting the SAW device of the present invention.

FIG. 4 is a flowchart for illustrating a method for manufacturing a SAW device having multiple filter bands according to the present invention.

FIG. 5 is a reference diagram illustrating, as images, a manufacturing process of the SAW device having multiple filter bands shown in FIG. 4.

FIG. 6 illustrates, as images, a process of forming a wiring defect prevention layer.

FIG. 7 is a reference diagram for illustrating differences between a SAW device formed by the manufacturing method according to the present invention and a conventional SAW device.

### DETAILED DESCRIPTION

The terms used herein are to explain particular embodiments and not intended to limit the present invention. As used herein, singular forms may include plural forms unless particularly defined otherwise in context.

As used herein, the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof. Additionally, the embodiment in the detailed description will be described with sectional views and/or plan views as ideal exemplary views of the present invention. Accordingly, embodiments of the present invention are not limited to the specific forms shown, but also include modifications in form as needed. Therefore, the regions illustrated in the drawings have general properties, and the shapes of the regions illustrated in the drawings are merely for exemplifying specific forms of the regions of the device, and are not intended to limit the scope of the invention.

Hereinafter, a surface acoustic wave (SAW) device having multiple filter bands according to the present invention and a method for manufacturing the same will be described with reference to the drawings.

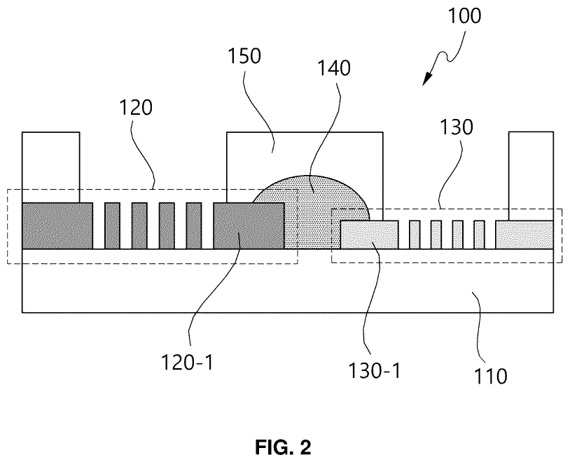

FIG. 2 is a side view illustrating a SAW device 100 having multiple filter bands of the present invention.

Referring to FIG. 2, the SAW device 100 includes a substrate 110, a first electrode layer 120, a second electrode layer 130, a wiring defect prevention layer 140, and a metal wiring layer 150.

The substrate 110 may be a semiconductor substrate, for which a conventional silicon wafer may be used, and preferably, a high-resistance silicon substrate (HRS) may be used.

The first electrode layer 120 is formed on an upper part of the substrate 110. The first electrode layer 120 is formed by depositing a predetermined material on the upper portion of the substrate 110 and then patterning the deposited material.

The material used for the first electrode layer 120 may be a conventional conductive material such as a metal, and preferably may be one selected from aluminum (Al), tungsten (W), gold (Au), platinum (Pt), nickel (Ni), titanium (Ti), chromium (Cr), palladium (Pd), ruthenium (Ru), rhenium (Re), and molybdenum (Mo).

The second electrode layer 130 is likewise formed by depositing a predetermined material on the substrate 110 and then patterning the deposited material. The material used for the second electrode layer 130 may be the same conductive material as that used for the first electrode layer 120, and may be one selected from aluminum (Al), tungsten (W), gold (Au), platinum (Pt), nickel (Ni), titanium (Ti), chromium (Cr), palladium (Pd), ruthenium (Ru), rhenium (Re), and molybdenum (Mo).

The wiring defect prevention layer 140 is formed on upper portions of one end 120-1 of the first electrode layer 120 and the other end 130-1 of the second electrode layer 130 so as to surround one end of the first electrode layer 120 and the other end of the second electrode layer 130. Here, the one end 120-1 and the other end 130-1 may be formed to have different thicknesses in the height direction. In addition, the one end 120-1 and the other end 130-1 may be signal wiring or ground wiring.

The wiring defect prevention layer 140 may include a photosensitive agent, a binder, a solvent, and an additive.

The photosensitive agent may include a diazonaphthoquinone material, the binder may include a novolac resin, a PHS+acrylate resin, or a PHS+cycloolefin resin, and the solvent may include propylene glycol monomethyl ether acetate (PGMEA), propylene glycol monomethyl ether (PGME), γ-butyrolactone (GBL), ethylene glycol butyl ether (EGBE), glycol ethers, cyclohexanone, or anisole.

Table 1 below shows materials constituting the wiring defect prevention layer 140, which may vary depending on the wavelength of light (e.g., 365 nm, 248 nm, 193 nm) irradiated in the exposure process for manufacturing the SAW device 100.

TABLE 1

| Classification | Component | | | |
|---|---|---|---|---|
| by wavelength | Photosensitive agent | Binder resin | Solvent | Additive |
| 365 nm | DNQ-based | novolac resin-based | PGMEA, PGME, | surfactant, |
| (i-line) | photosensitive agent | phenol resin | GBL, EGBE | defoamer, |
| | (diazonaphthoquinone) | | | dye, |
| 248 nm | PAG-based | PHS + Acrylate or | PGMEA, PGME, | curing |
| (KrF) | photosensitive agent | PHS + Cycloolefin | GBL, glycol | accelerator, |
| | (photoacid generator) | resin | ethers | base |
| 193 nm | PAG-based | acrylate resin or | PGMEA, PGME, | generator |
| (ArF) | photosensitive agent | COMA-based resin | GBL, | |
| | (photoacid generator) | | cyclohexanone, | |
| | | | anisole | |

The wiring defect prevention layer 140 may surround one end of the first electrode layer and the other end of the second electrode layer such that the following equation is satisfied.

In this case, a length of an overlap width of the wiring defect prevention layer 140 with one end of the first electrode layer 120 and the other end of the second electrode layer 130 may be determined by the width of the metal wiring layer 150, the spacing width between one end of the first electrode layer 120 and the other end of the second electrode layer 130, and the width of the metal wiring layer 150.

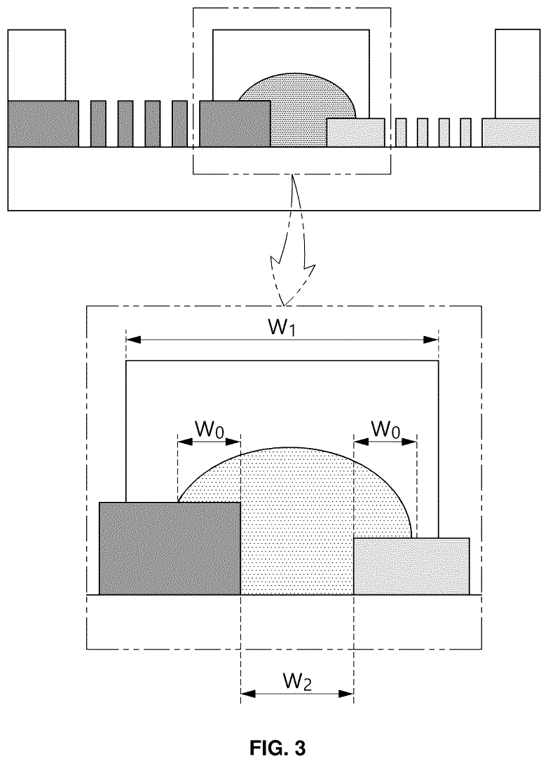

FIG. 3 is a reference diagram illustrating the structure of the wiring defect prevention layer 140 constituting the SAW device 100 of the present invention.

Referring to FIG. 3, the overlap width W0 of the wiring defect prevention layer 140 may be determined using the following Equation 1.

$$W 0 < ( W 1 - W 2 ) / 2 \qquad [ Equation 1 ]$$

Here, W0 refers to an overlap width between the one end 120-1 of the first electrode layer 120 or the other end 130-1 of the second electrode layer 130 and the wiring defect prevention layer 140, W1 refers to a width of the metal wiring layer 150, and W2 refers to a spacing width between one end 120-1 of the first electrode layer 120 and the other end 130-1 of the second electrode layer 130.

The metal wiring layer 150 is formed on upper portions of the first electrode layer 120, the second electrode layer 130, and the wiring defect prevention layer 140. The metal wiring layer 150 may be formed on an upper portion of the wiring defect prevention layer 140 with a predetermined thickness and width so as to completely surround the wiring defect prevention layer 140.

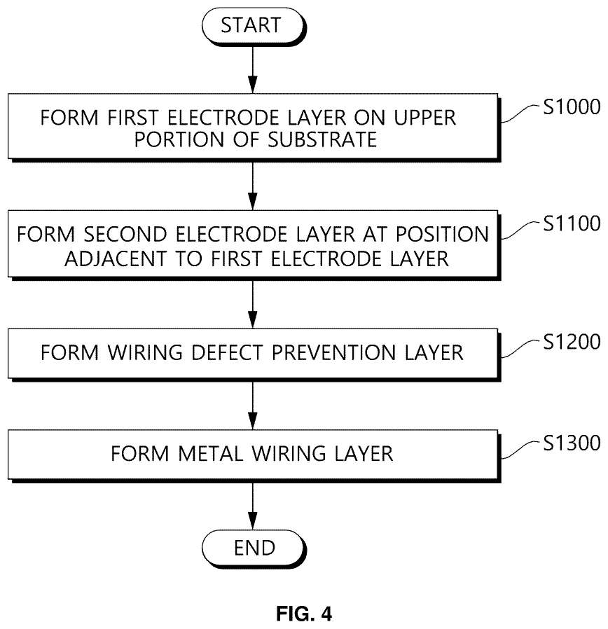

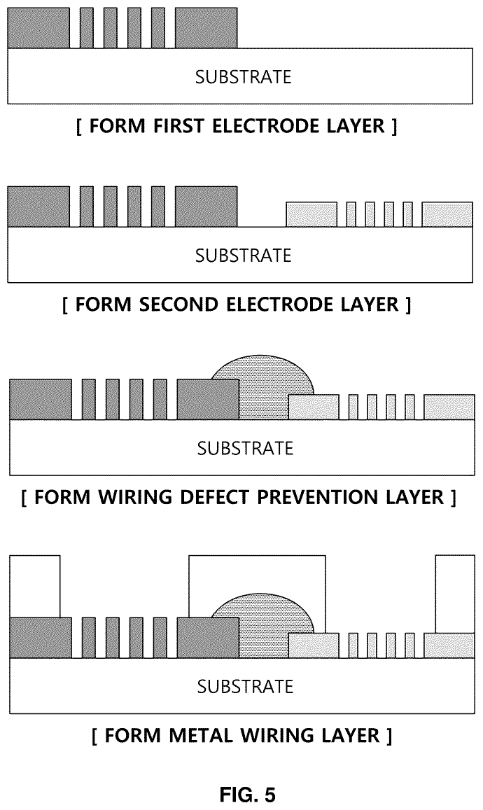

FIG. 4 is a flowchart for illustrating a method for manufacturing a SAW device having multiple filter bands according to the present invention, and FIG. 5 is a reference diagram illustrating, as images, a manufacturing process of the SAW device having multiple filter bands shown in FIG. 4.

First, a first electrode layer is formed on an upper portion of a substrate (step S1000). The first electrode layer may be formed by depositing a predetermined material on the upper portion of the substrate and then patterning the deposited material.

After step S1000, a second electrode layer is formed at a position adjacent to a formation position of the first electrode layer on the upper portion of the substrate (step S1100).

The second electrode layer may likewise be formed by depositing a predetermined material on the upper portion of the substrate and then patterning the deposited material. The material used for the second electrode layer may be the same conductive material as that used for the first electrode layer.

After step S1100, a wiring defect prevention layer is formed so as to surround one end of the first electrode layer and the other end of the second electrode layer (step S1200).

The step of forming the wiring defect prevention layer may include surrounding one end of the first electrode layer and the other end of the second electrode layer such that Equation 1 described above is satisfied.

The wiring defect prevention layer may include a photosensitive agent, a binder, a solvent, and an additive. The photosensitive agent may include a diazonaphthoquinone material, the binder may include a novolac resin, a PHS+acrylate resin, or a PHS+cycloolefin resin, and the solvent may include propylene glycol monomethyl ether acetate (PGMEA), propylene glycol monomethyl ether (PGME), γ-butyrolactone (GBL), ethylene glycol butyl ether (EGBE), glycol ethers, cyclohexanone, or anisole.

The specific process for forming the wiring defect prevention layer is as follows.

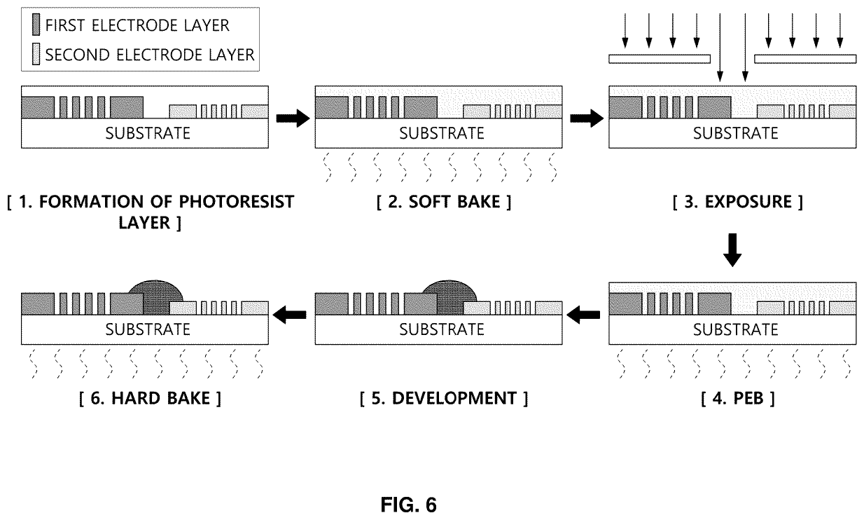

FIG. 6 illustrates, as images, a process of forming a wiring defect prevention layer.

Referring to FIG. 6, first, the step of forming the wiring defect prevention layer may include forming a photoresist layer on upper portions of the first electrode layer and the second electrode layer.

After spraying photoresist onto upper portions of the first electrode layer and the second electrode layer, spin coating may be performed through rotation of the substrate.

Thereafter, a soft bake process is performed to evaporate solvent from the photoresist layer. At this time, the applied heat may be at a temperature of 90° C. to 130° C.

Thereafter, an exposure process is performed on the photoresist layer. That is, ultraviolet (UV) light is used to induce a chemical modification of a polymer resin in the photoresist layer to form a wiring defect prevention pattern.

Thereafter, a post-exposure bake (PEB) process is performed. That is, the PEB process reduces physical stress of the photoresist layer generated by exposure and induces activation of a chemical reaction to planarize the wiring defect prevention pattern. For this purpose, the PEB process may be performed at a temperature of 90° C. to 130° C.

Thereafter, a development process is performed. For the development process, a TMAH-based developer solution may be used. Through the development process, unnecessary portions of the photoresist layer are removed.

Thereafter, a hard bake process is performed to remove unnecessary photoresist layer remaining after development and to harden the wiring defect prevention pattern, thereby forming a wiring defect prevention layer. For this purpose, a process temperature higher than that of the soft bake is generally required, and it needs to be equal to or higher than a temperature at which plastic flow or glass transition occurs.

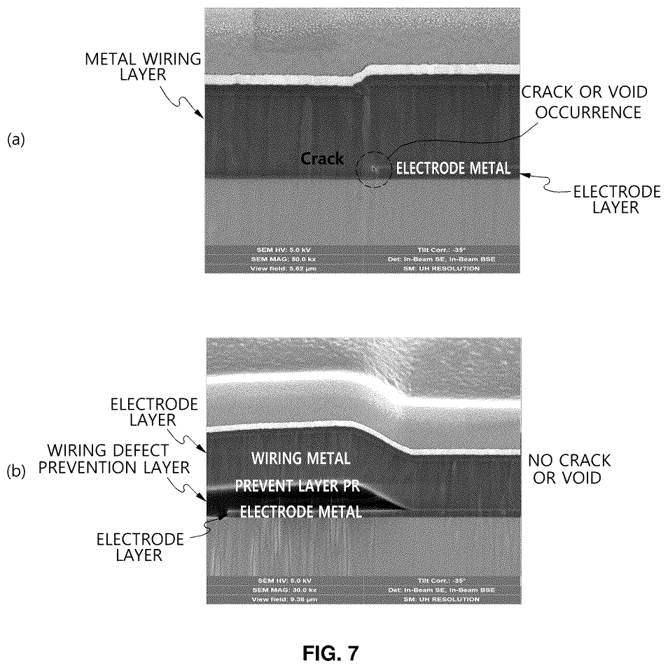

After step S1200, a metal wiring layer is formed on upper portions of the first electrode layer, the second electrode layer, and the wiring defect prevention layer (step S1300). The metal wiring layer is formed on an upper portion of the wiring defect prevention layer so as to completely surround the wiring defect prevention layer. FIG. 7 is a reference diagram for illustrating differences between a SAW device formed by the manufacturing method according to the present invention and a conventional SAW device.

FIG. 7(a) corresponds to a conventional SAW device, in which a metal wiring layer is directly formed on an electrode layer, and cracks or voids are observed in the metal wiring layer. However, as shown in FIG. 7(b), according to the present invention, a wiring defect prevention layer is first formed on the electrode layer before forming the metal wiring layer thereon, and then the metal wiring layer is formed. Thus, due to the buffering function of the wiring defect prevention layer, occurrence of cracks or voids in the metal wiring layer can be prevented.

Although the technical idea of the present invention has been described with reference to the accompanying drawings, this is provided to illustrate only preferred embodiments of the present invention and does not limit the present invention.

Therefore, the present invention is not limited to the specific preferred embodiments described above, and it is obvious to those skilled in the art that many modifications may be made thereto without departing from the subject matter of the present disclosure set forth in the appended claims, and such modifications fall in the scope of the appended claims.

### REFERENCE NUMERALS

100: SAW DEVICE
110: SUBSTRATE
120: FIRST ELECTRODE LAYER
130: SECOND ELECTRODE LAYER
140: WIRING DEFECT PREVENTION LAYER
150: METAL WIRING LAYER

What is claimed:

1. A method for manufacturing a surface acoustic wave (SAW) device having multiple filter bands, the method comprising:
forming a first electrode layer on an upper portion of a substrate;
forming a second electrode layer at a position adjacent to a formation position of the first electrode layer on the upper portion of the substrate;
forming a wiring defect prevention layer surrounding one end of the first electrode layer and the other end of the second electrode layer; and
forming a metal wiring layer on upper portions of the first electrode layer, the second electrode layer, and the wiring defect prevention layer.

2. The method of claim 1, wherein the forming of the wiring defect prevention layer comprises forming the wiring defect prevention layer to surround the one end of the first electrode layer and the other end of the second electrode layer such that the following equation is satisfied:
$$W 0 < ( W 1 - W 2 ) / 2 \qquad [ Equation ]$$
wherein W0 refers to an overlap width between the one end of the first electrode layer or the other end of the second electrode layer and the wiring defect prevention layer, W1 refers to a width of the metal wiring layer, and W2 refers to a spacing width between one end of the first electrode layer and the other end of the second electrode layer.

3. The method of claim 1, wherein the forming of the wiring defect prevention layer comprises forming a photoresist layer on the upper portions of the first electrode layer and the second electrode layer after the first electrode layer and the second electrode layer are formed, and forming the wiring defect prevention layer through an exposure process and a development process on the photoresist layer.

4. The method of claim 3, wherein the wiring defect prevention layer comprises a material in which a photosensitive agent, a binder, a solvent, and an additive are mixed, the photosensitive agent comprises a diazonaphthoquinone material, the binder comprises a novolac resin, a PHS+acrylate resin, or a PHS+cycloolefin resin, and the solvent comprises propylene glycol monomethyl ether acetate (PGMEA), propylene glycol monomethyl ether (PGME), γ-butyrolactone (GBL), ethylene glycol butyl ether (EGBE), glycol ethers, cyclohexanone, or anisole.

5. A surface acoustic wave (SAW) device having multiple filter bands, comprising:
a substrate;
a first electrode layer formed on an upper portion of the substrate;
a second electrode layer formed at a position adjacent to a formation position of the first electrode layer on the upper portion of the substrate;
a wiring defect prevention layer formed on an upper portion of one end of the first electrode layer and an upper portion of the other end of the second electrode layer so as to surround the one end of the first electrode layer and the other end of the second electrode layer; and
a metal wiring layer formed on upper portions of the first electrode layer, the second electrode layer, and the wiring defect prevention layer.

6. The SAW device of claim 5, wherein the wiring defect prevention layer surrounds the one end of the first electrode layer and the other end of the second electrode layer so as to satisfy the following equation:
$$W 0 < ( W 1 - W 2 ) / 2 \qquad [ Equation ]$$
wherein W0 refers to an overlap width between the one end of the first electrode layer or the other end of the second electrode layer and the wiring defect prevention layer, W1 refers to a width of the metal wiring layer, and W2 refers to a spacing width between one end of the first electrode layer and the other end of the second electrode layer.

7. The SAW device of claim 5, wherein the wiring defect prevention layer comprises a material in which a photosensitive agent, a binder, a solvent, and an additive are mixed, the photosensitive agent comprises a diazonaphthoquinone material, the binder comprises a novolac resin, a PHS+acrylate resin, or a PHS+cycloolefin resin, and the solvent comprises propylene glycol monomethyl ether acetate (PGMEA), propylene glycol monomethyl ether (PGME), γ-butyrolactone (GBL), ethylene glycol butyl ether (EGBE), glycol ethers, cyclohexanone, or anisole.

8. The SAW device of claim 5, wherein the one end of the first electrode layer and the other end of the second electrode layer have different heights.
